(19) United States
(12) Patent Application Publication
(10) Pub. No.: US 2025/0191639 A1
(43) Pub. Date: Jun. 12, 2025

(54) SEMICONDUCTOR DEVICE HAVING GEAR DOWN MODE

(71) Applicant: MICRON TECHNOLOGY, INC., BOISE, ID (US)

(72) Inventors: Yoshiya Komatsu, Kanagawa (JP); Yutaka Uemura, Tokyo (JP)

(73) Assignee: MICRON TECHNOLOGY, INC., Boise, ID (US)

(21) Appl. No.: 18/781,145

(22) Filed: Jul. 23, 2024

Related U.S. Application Data
(60) Provisional application No. 63/608,998, filed on Dec. 12, 2023.

(51) Int. Cl. G11C 11/4076; G11C 11/4093

(52) U.S. Cl. CPC G11C 11/4076; G11C 11/4093

(57) ABSTRACT

An example apparatus includes a clock divider configured to divide an original clock signal to generate a first clock signal and a second clock signal having different phase from the first clock signal; a first clock path; a second clock path; and a control circuit configured to: in a first operation mode, supply at least one pulse of the first clock signal to the first clock path and at least one pulse of the second clock signal to the second clock path; and in a second operation mode, supply at least one pulse of one of the first and second clock signals to the first clock path and supply at least one pulse of one of the first and second clock signals to the second clock path.

### CROSS REFERENCE TO RELATED APPLICATION(S)

This application claims priority to U.S. Provisional Application No. 63/608,998, filed Dec. 12, 2023. The aforementioned application is incorporated herein by reference, in its entirety, for any purpose.

### BACKGROUND

A DDR5 SDRAM has a gear down mode in which the pulse width of a chip selection signal CS_n is increased from one clock cycle to two clock cycles. In an operation in the gear down mode, a divided clock signal is supplied only to one of clock paths, but is not supplied to the other clock path. Therefore, influences of NBTI (Negative Bias Temperature Instability) and PBTI (Positive Bias Temperature Instability) become uneven between the two clock paths.

### BRIEF DESCRIPTION OF THE DRAWINGS

FIG. 1 is a block diagram showing a configuration of a semiconductor memory device according to an embodiment of the present disclosure;

FIG. 2 is a circuit diagram of a gear down control circuit according to a first embodiment;

FIG. 3 is a timing chart for explaining an operation of the gear down control circuit shown in FIG. 2 in a normal mode;

FIG. 4 is a timing chart for explaining an operation of the gear down control circuit shown in FIG. 2 in a gear down mode;

FIG. 5 is a circuit diagram of a gear down control circuit according to a second embodiment;

FIG. 6 is a timing chart for explaining an operation of the gear down control circuit shown in FIG. 5 in the gear down mode;

FIG. 7 is a circuit diagram of a gear down control circuit according to a third embodiment; and

FIG. 8 is a timing chart for explaining an operation of the gear down control circuit shown in FIG. 7 in the gear down mode.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

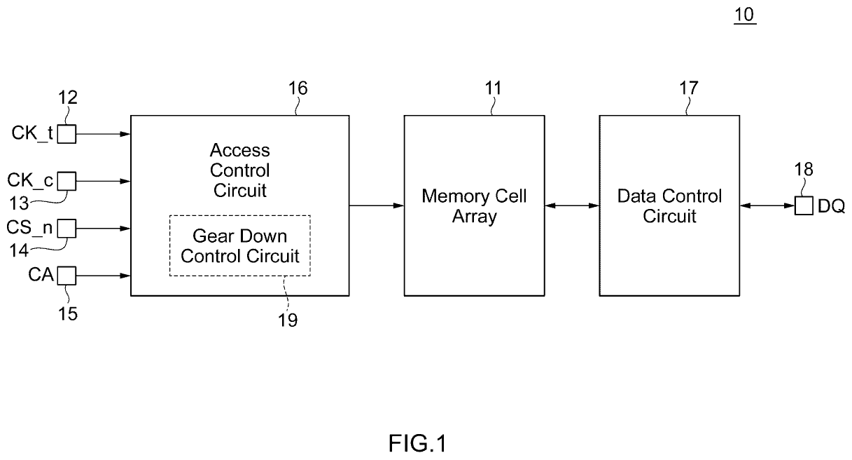

FIG. 1 is a block diagram showing a configuration of a semiconductor memory device 10 according to an embodiment of the present disclosure. The semiconductor memory device 10 shown in FIG. 1 is a DDR5 DRAM and includes a memory cell array 11. When access is made to the memory cell array 11, a chip selection signal CS_n, which is active when being at a low level, is input to a chip selection terminal 14 synchronously with clock signals CK_t and CK_c respectively input to clock terminals 12 and 13, and a command address signal CA is input to a command address terminal 15. The clock signals CK_t and CK_c, the chip selection signal CS_n, and the command address signal CA are supplied to an access control circuit 16. The access control circuit 16 decodes the command address signal CA and counts the latency, for example. In a case where a command included in the command address signal CA indicates a read operation, the access control circuit 16 makes rad access to a memory cell included in the memory cell array 11 based on an address included in the command address signal CA. Read data DQ read out from the memory cell thus accessed is output to outside from a data I/O terminal 18 via a data control circuit 17. In a case where the command included in the command address signal CA indicates a write operation, write data DQ input from the outside to the data I/O terminal 18 is transferred to the memory cell array 11 via the data control circuit 17. The write data DQ transferred to the memory cell array 11 is written to a memory cell included in the memory cell array 11 based on an address included in the command address signal CA.

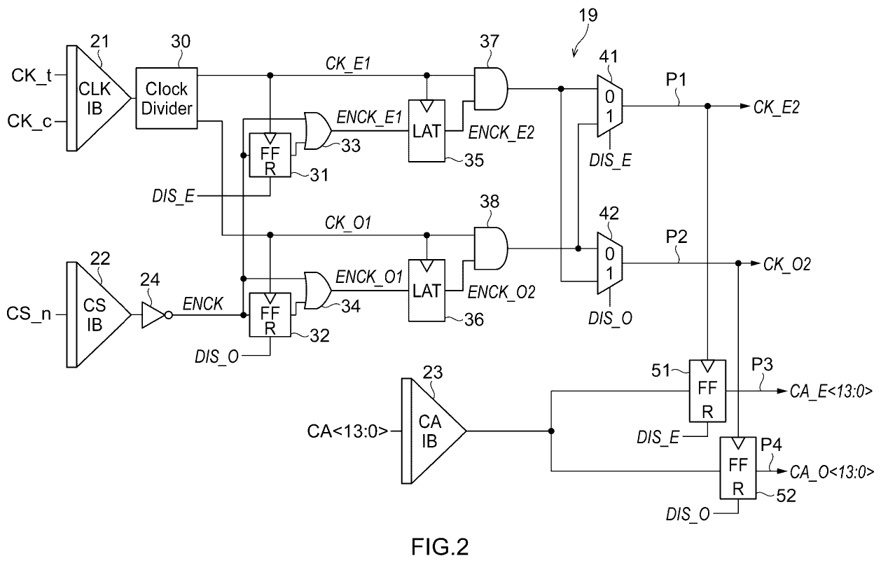

FIG. 2 is a circuit diagram of a gear down control circuit 19 according to a first embodiment. The gear down control circuit 19 is included in the access control circuit 16. The access control circuit 16 includes an input buffer 21 receiving the clock signals CK_t and CK_c, which are complementary, an input buffer 22 receiving the chip selection signal CS_n, and an input buffer 23 receiving a command address signal CA<13:0>. The output of the input buffer 21 is supplied to a dividing circuit 30. The dividing circuit 30 divides the clock signals CK_t and CK_c to generate an internal clock signal CK_E1 and an internal clock signal CK_O1. The output of the input buffer 22 is inverted by an inverter 24, whereby an enable signal ENCK is generated. The enable signal ENCK is supplied to input nodes of latch circuits 31 and 32 that am portions of the gear down control circuit 19, and is supplied to one input node of an OR gate circuit 33 and one input node of an OR gate circuit 34. In the latch circuits 31 and 32, the internal clock signals CK_E1 and CK_O1 are supplied to clock nodes, respectively. In FIG. 2, “FF” indicates that the latch circuits 31 and 32 are flip-flop latch circuits. The latch circuits 31 and 32 each latch a signal input thereto synchronously with a rising edge of the corresponding internal clock signal CK_E1 or CK_O1. The latch circuit 31 is reset when a disable signal DIS_E is activated. The latch circuit 32 is reset when a disable signal DIS_O is activated. In a gear down mode, one of the disable signals DIS_E and DIS_O is activated. The output of the latch circuit 31 is supplied to the other input node of the OR gate circuit 33. The output of the latch circuit 32 is supplied to the other input node of the OR gate circuit 34.

An enable signal ENCK_E1 output from the OR gate circuit 33 is supplied to an input node of a latch circuit 35. An enable signal ENCK_O1 output from the OR gate circuit 34 is supplied to an input node of a latch circuit 36. In the latch circuits 35 and 36, the internal clock signals CK_E1 and CK_O1 are supplied to clock nodes, respectively. In FIG. 2, “LAT” indicates that the latch circuits 35 and 36 are through latch circuits. Each of the latch circuits 35 and 36 allows an input signal to pass therethrough when the corresponding one of the internal clock signals CK_E1 and CK_O1 is at a low level, and maintains the previous state when the corresponding one of the internal clock signals CK_E1 and CK_O1 is changed from a low level to a high level. An enable signal ENCK_E2 output from the latch circuit 35 is supplied to one input node of an AND gate circuit 37. An enable signal ENCK_O2 output from the latch circuit 36 is supplied to one input node of an AND gate circuit 38. The internal clock signals CK_E1 and CK_O1 are supplied to the other input nodes of the AND gate circuits 37 and 38, respectively.

The gear down control circuit 19 includes multiplexers 41 and 42. An output node of the AND gate circuit 37 is coupled to an input node “0” of the multiplexer 41 and an input node “1” of the multiplexer 42, An output node of the AND gate circuit 38 is coupled to an input node “1” of the multiplexer 41 and an input node “0” of the multiplexer 42. The multiplexer 41 selects the input node “0” when the disable signal DIS_E is at a level 0 (inactive state) and selects the input node “1” when the disable signal DIS_E is at a level 1 (active state). The multiplexer 42 selects the input node “0” when the disable signal DIS_O is at the level 0 (inactive state) and selects the input node “1” when the disable signal DIS_O is at the level 1 (active state). Output nodes of the multiplexers 41 and 42 are coupled to clock paths P1 and P2, respectively. The clock paths P1 and P2 respectively supply internal clock signals CK_E2 and CK_O2 to various circuits in the subsequent stages.

The command address signal CA<13:0> taken in by the input buffer 23 is supplied to input nodes of latch circuits 51 and 52 in common. The latch circuits 51 and 52 each latch a signal input thereto synchronously with a rising edge of the corresponding one of the internal clock signals CK_E2 and CK_O2. The latch circuit 51 is reset when the disable signal DIS_E is activated. The latch circuit 52 is reset when the disable signal DIS_O is activated. Output nodes of the latch circuits 51 and 52 are coupled to command address paths P3 and P4, respectively. The command address paths P3 and P4 respectively supply command address signals CA_E<13:0> and CA_O<13:0> to a command decoder and an address decoder (both not shown).

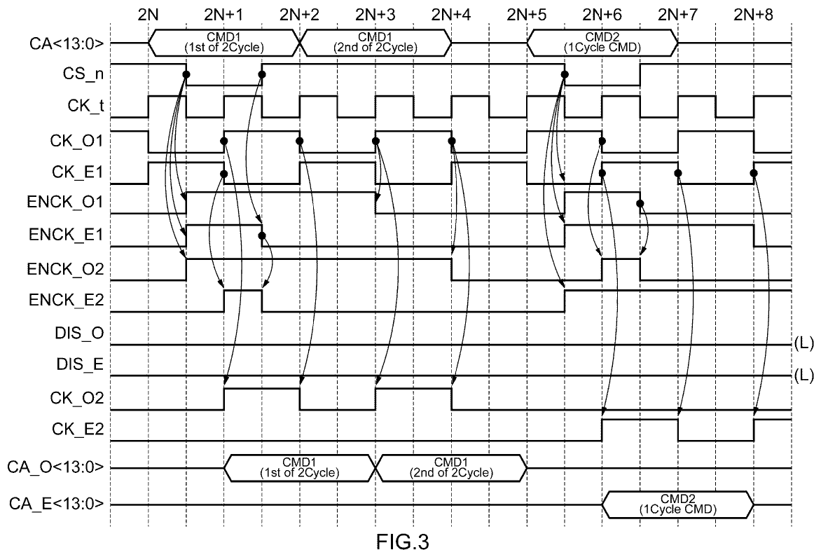

FIG. 3 is a timing chart for explaining an operation of the gear down control circuit 19 shown in FIG. 2 in a normal mode. In the normal mode, the pulse width of the chip selection signal CS_n is one clock cycle. In addition, in the normal mode, the disable signals DIS_E and DIS_O are both at the level 0 (inactive state).

In the example shown in FIG. 3, the chip selection signal CS_n is activated at a timing 2N+1 and a timing 2N+6. A command CMD1 input to correspond to the chip selection signal CS_n synchronized with the timing 2N+1 is input in two parts at the timing 2N+1 and a timing 2N+3. A command CMD2 input to correspond to the chip selection signal CS_n synchronized with the timing 2N+6 is input at the timing 2N+6.

As shown in FIG. 3, the internal clock signals CK_E1 and CK_O1 generated by the dividing circuit 30 have twice the period of the clock signal CK_t supplied from the outside and have phases reversed from each other. The internal clock signal CK_O1 rises synchronously with odd-numbered rising edges (2N+1, 2N+3, 2N+5, . . . ) of the clock signal CK_t and falls synchronously with even-numbered rising edges (2N+2, 2N+4, 2N+6, . . . ) of the clock signal CK_t. The internal clock signal CK_E1 rises synchronously with the even-numbered rising edges (2N+2, 2N+4, 2N+6, . . . ) of the clock signal CK_t and falls synchronously with the odd-numbered rising edges (2N+1, 2N+3, 2N+5, . . . ).

First, when the chip selection signal CS_n falls in order to allow the command CMD1 to be input, the enable signals ENCK_O1, ENCK_E1, and ENCK_O2 rise synchronously with this falling. Thereafter, the latch circuit 32 performs a latch operation responsive to a rising edge of the internal clock signal CK_O1 appearing at the timing 2N+1. The enable signal ENCK_O1 is thus kept high until the timing 2N+3 at which the next rising edge of the internal clock signal CK_O1 appears. Further, the enable signal ENCK_O2 is kept high until the timing 2N+4 at which a falling edge of the internal clock signal CK_O1 appears. Consequently, in a time period in which the enable signal ENCK_O2 is at a high level, at least one pulse of the internal clock signal CK_O1 is extracted and supplied to the clock path P2 as the internal clock signal CK_O2 via the multiplexer 42 in which the input node “0” is selected. The internal clock signal CK_O2 is supplied to the latch circuit 52 through the clock path P2. The command address signal CA_O<13:0> is thus supplied to the command address path P4 synchronously with the internal clock signal CK_O2. On the other hand, the internal clock signal CK_E2 on the clock path P1 is kept low because both the enable signal ENCK_E2 and the internal clock signal CK_E1 are not at a high level at the same time.

Next, when the chip selection signal CS_n falls in order to allow the command CMD2 to be input, the enable signals ENCK_O1, ENCK_E1, and ENCK_E2 rise synchronously with this falling. Thereafter, the latch circuit 31 performs a latch operation responsive to a rising edge of the internal clock signal CK_E1 appearing at the timing 2N+6. The enable signal ENCK_E1 is thus kept high until a timing 2N+8 at which the next rising edge of the internal clock signal CK_E1 appears. Further, the enable signal ENCK_E2 is kept high until a timing at which a falling edge of the internal clock signal CK_E1 appears. Consequently, in a time period in which the enable signal ENCK_E2 is at a high level, at least one pulse of the internal clock signal CK_E1 is extracted and supplied to the clock path P1 as the internal clock signal CK_E2 via the multiplexer 41 in which the input node “0” is selected. The internal clock signal CK_E2 is supplied to the latch circuit 51 through the clock path P1. The command address signal CA_E<13:0> is thus supplied to the command address path P3 synchronously with the internal clock signal CK_E1. On the other hand, the internal clock signal CK_O2 on the clock path P2 is kept low because both the enable signal ENCK_O2 and the internal clock signal CK_O1 are not at a high level at the same time.

As described above, in the normal mode, the internal clock signal CK_O2 on the clock path P2 toggles in a case where the chip selection signal CS_n is activated synchronously with an odd-numbered rising edge of the clock signal CK_t, and the internal clock signal CK_E2 on the clock path P1 toggles in a case where the chip selection signal CS_n is activated synchronously with an even-numbered rising edge of the clock signal CK_t. Since the probability that activation of the chip selection signal CS_n is synchronized with an odd-numbered rising edge of the clock signal CK_t and the probability that activation of the chip selection signal CS_n is synchronized with an even-numbered rising edge of the clock signal CK_t are both about 50%, the influences of NBTI and PBTI are approximately the same between the clock path P1 and the clock path P2. Therefore, there arises no difference in characteristics between the clock path P1 and the clock path P2 in an operation in the normal mode.

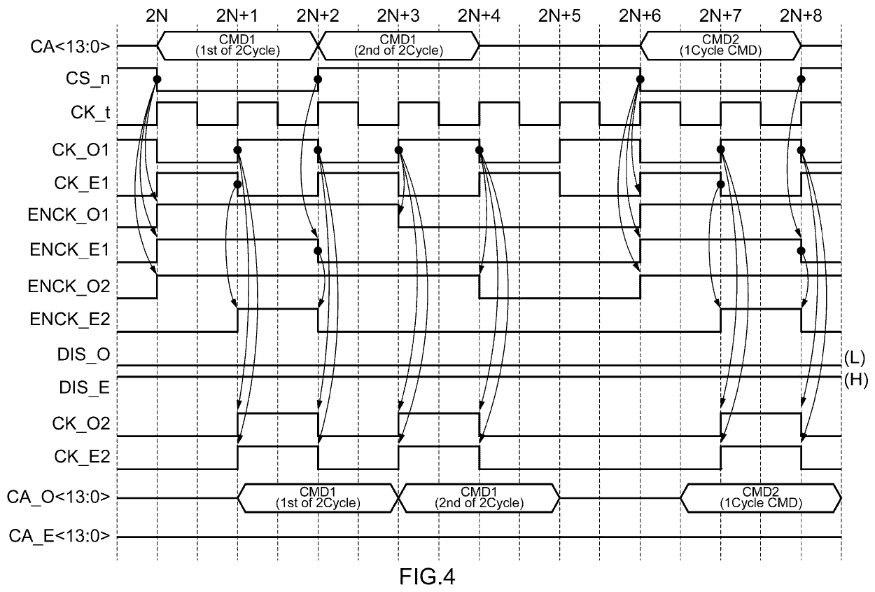

FIG. 4 is a timing chart for explaining an operation of the gear down control circuit 19 shown in FIG. 2 in a gear down mode. In the gear down mode, the pulse width of the chip selection signal CS_n is increased to two clock cycles. Therefore, activation of the chip selection signal CS_n is fixed to odd-numbered or even-numbered rising edges of the clock signal CK_t. In a case where activation of the chip selection signal CS_n is fixed to odd-numbered rising edges of the clock signal CK_t in the gear down mode, the disable signal DIS_E is at the level 1 (active state), and the disable signal DIS_O is at the level 0 (inactive state). To the contrary, in a case where activation of the chip selection signal CS_n is fixed to even-numbered rising edges of the clock signal CK_t in the gear down mode, the disable signal DIS_E is at the level 0 (inactive state), and the disable signal DIS_O is at the level 1 (active state).

In the example shown in FIG. 4, activation of the chip selection signal CS_n is fixed to odd-numbered rising edges of the clock signal CK_t. The first activation of the chip selection signal CS_n is synchronized with the timing 2N+1, and the second activation of the chip selection signal CS_n is synchronized with a timing 2N+7. The command CMD1, input to correspond to the chip selection signal CS_n synchronized with the timing 2N+1, is input in two parts at the timing 2N+1 and the timing 2N+3. The command CMD2, input to correspond to the chip selection signal CS_n synchronized with the timing 2N+7, is input at the timing 2N+7.

As shown in FIG. 4, the waveforms of the respective signals in the gear down mode are basically the same as those in the normal mode. However, in the example shown in FIG. 4, since the disable signal DIS_E is at the level 1 (active state) and the disable signal DIS_O is at the level 0 (inactive state), the multiplexer 41 selects its input node “1”. Therefore, the internal clock signal CK_E2 on the clock path P1 has the same waveform as the internal clock signal CK_O2 on the clock path P2. The influences of NBTI and PBTI thus become the same between the clock path P1 and the clock path P2, and therefore there arises no difference in characteristics between the clock path P1 and the clock path P2. In the present example, the internal clock signal CK_E2 on the clock path P1 is originally unnecessary and, if this signal is left available for use, causes a malfunction in a subsequent circuit. However, since the disable signal DIS_E is at the level 1 (active state) and the command address path P3 is interrupted by the latch circuit 51 in the example shown in FIG. 4, the command address signal CA_E<13:0> on the command address path P3 does not change.

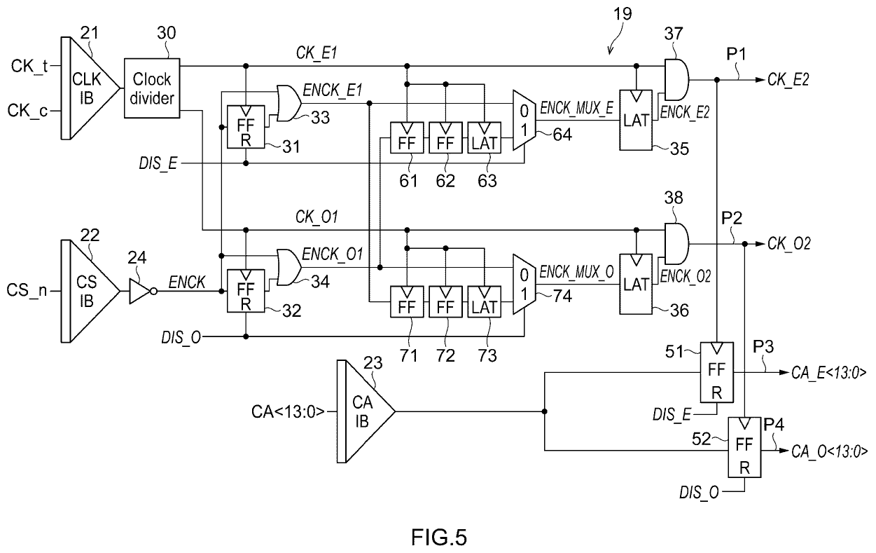

FIG. 5 is a circuit diagram of the gear down control circuit 19 according to a second embodiment. The gear down control circuit 19 shown in FIG. 5 is different from the gear down control circuit 19 shown in FIG. 2 in that the multiplexers 41 and 42 are placed with latch circuits 61 to 63 and 71 to 73 and multiplexers 64 and 74.

The latch circuits 61 to 63 are connected in cascade connection and each perform a latch operation synchronously with the internal clock signal CK_E1. The enable signal ENCK_O1 is input to the latch circuit 61 in the first stage. The output of the latch circuit 63 in the last stage is supplied to an input node “1” of the multiplexer 64. The enable signal ENCK_E1 is supplied to an input node “0” of the multiplexer 64. The multiplexer 64 selects the input node “0” when the disable signal DIS_E is at the level 0 (inactive state) and selects the input node “1” when the disable signal DIS_E is at the level 1 (active state). An enable signal ENCK_MUX_E output from the multiplexer 64 is supplied to the input node of the latch circuit 35.

The latch circuits 71 to 73 are connected in cascade connection and each perform a latch operation synchronously with the internal clock signal CK_O1. The enable signal ENCK_E1 is input to the latch circuit 71 in the first stage. The output of the latch circuit 73 in the last stage is supplied to an input node “1” of the multiplexer 74. The enable signal ENCK_O1 is supplied to an input node “0” of the multiplexer 74. The multiplexer 74 selects the input node “0” when the disable signal DIS_O is at the level 0 (inactive state) and selects the input node “1” when the disable signal DIS_O is at the level 1 (active state). An enable signal ENCK_MUX_O output from the multiplexer 74 is supplied to the input node of the latch circuit 36.

As described above, both the disable signals DIS_E and DIS_O are at the level 0 (inactive state) in the normal mode. Therefore, the operation waveforms in the gear down control circuit 19 shown in FIG. 5 are the same as the operation waveforms shown in FIG. 3.

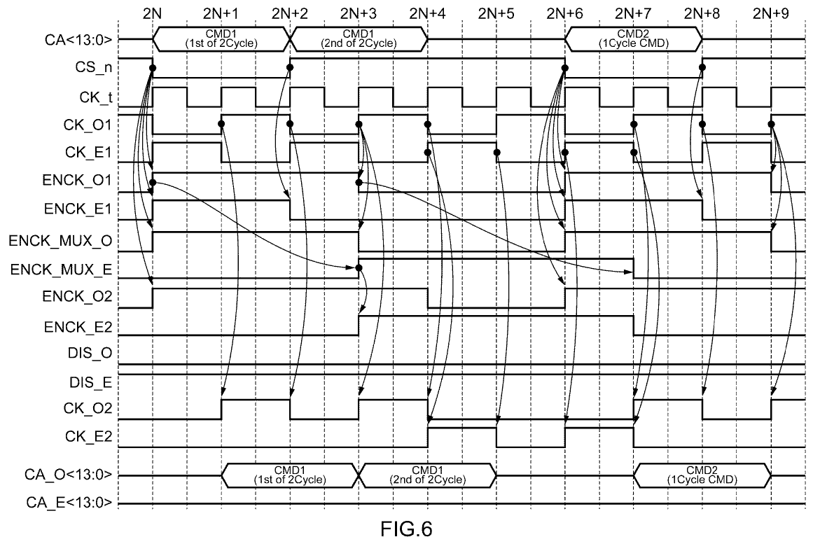

FIG. 6 is a timing chart for explaining an operation of the gear down control circuit 19 shown in FIG. 5 in the gear down mode. Input timings of the chip selection signal CS_n are the same as those in the example shown in FIG. 4.

First, when the chip selection signal CS_n falls in order to allow the command CMD1 to be input, the enable signals ENCK_O1, ENCK_E1, ENCK_MUX_O, and ENCK_O2 rise synchronously with this falling. Thereafter, the latch circuit 32 performs a latch operation responsive to a rising edge of the internal clock signal CK_O1 appearing at the timing 2N+1. The enable signals ENCK_O1 and ENCK_MUX_O are thus kept high until the timing 2N+3 at which the next rising edge of the internal clock signal CK_O1 appears. Further, the enable signal ENCK_O2 is kept high until the timing 2N+4 at which a falling edge of the internal clock signal CK_O1 appears. Consequently, in a time period in which the enable signal ENCK_O2 is at a high level, at least one pulse of the internal clock signal CK_O1 is extracted and supplied to the clock path P2 as the internal clock signal CK_O2.

The enable signal ENCK_O1 propagates through the latch circuits 61 to 63 synchronously with the internal clock signal CK_E1. When a high-level signal is output from the latch circuit 63 in the last stage, the enable signal ENCK_MUX_E rises via the multiplexer 64, so that the enable signal ENCK_E2 becomes high. Thereafter, when the output of the latch circuit 63 in the last stage changes to a low level, the enable signal ENCK_MUX_E falls via the multiplexer 64, so that the enable signal ENCK_E2 changes to a low level. Accordingly, in a time period in which the enable signal ENCK_E2 is at a high level, at least one pulse of the internal clock signal CK_E1 is extracted and supplied to the clock path P1 as the internal clock signal CK_E2.

As described above, in the gear down mode, the gear down control circuit 19 according to the present embodiment generates the enable signal ENCK_E2 based on the enable signal ENCK_O1 and generates the enable signal ENCK_O2 based on the enable signal ENCK_E1. Accordingly, insertion of a multiplexer or the like into the clock paths P1 and P2 is no longer necessary, and thus a delay of the internal clock signals CK_E2 and CK_O2 caused by the multiplexer or the like does not occur. In addition, a sufficient operation margin is ensured because the enable signal ENCK_O1 is synchronized with the internal clock signal CK_E1 and the enable signal ENCK_E1 is synchronized with the internal clock signal CK_O1.

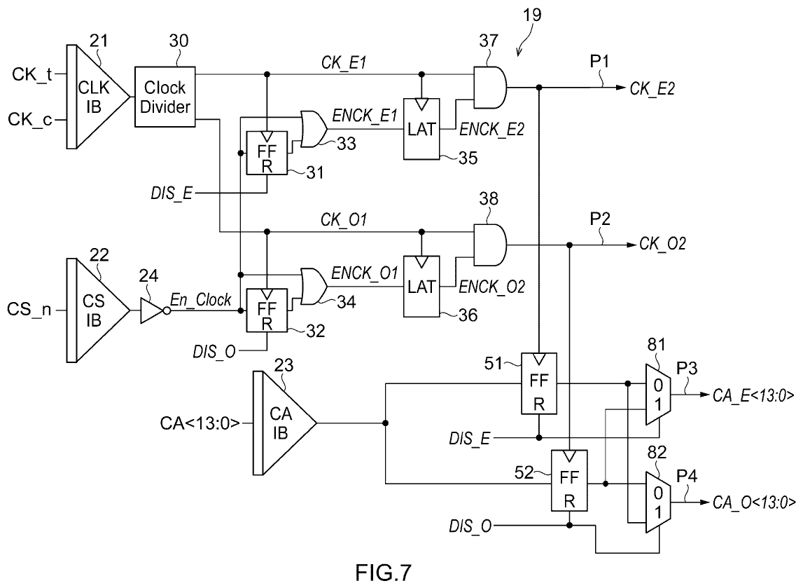

FIG. 7 is a circuit diagram of the gear down control circuit 19 according to a third embodiment. The gear down control circuit 19 shown in FIG. 7 is different from the gear down control circuit 19 shown in FIG. 2 in that the multiplexers 41 and 42 outputting the internal clock signals CK_E2 and CK_O2 are replaced with multiplexers 81 and 82 outputting the command address signals CA_E<13:0> and CA_O<13:0>.

An input node “0” of the multiplexer 81 and an input node “1” of the multiplexer 82 are coupled to the output node of the latch circuit 51. An input node “1” of the multiplexer 81 and an input node “0” of the multiplexer 82 are coupled to the output node of the latch circuit 52. The multiplexer 81 selects the input node “0” when the disable signal DIS_E is at the level 0 (inactive state) and selects the input node “1” when the disable signal DIS_E is at the level 1 (active state). The multiplexer 82 selects the input node “0” when the disable signal DIS_O is at the level 0 (inactive state) and selects the input node “1” when the disable signal DIS_O is at the level 1 (active state). Output nodes of the multiplexers 81 and 82 are coupled to the command address paths P3 and P4, respectively.

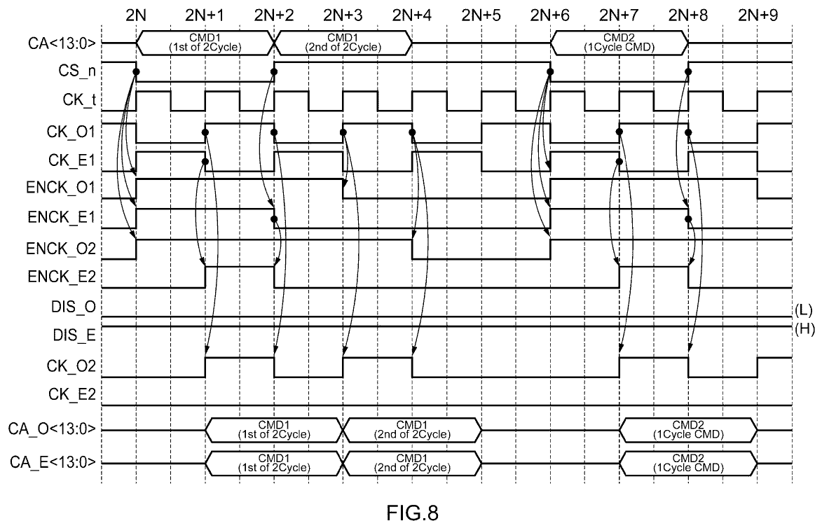

FIG. 8 is a timing chart for explaining an operation of the gear down control circuit 19 shown in FIG. 7 in the gear down mode. The input timings of the chip selection signal CS_n are the same as those in the example shown in FIG. 4.

In the example shown in FIG. 8, the disable signal DIS_E is at the level 1 (active state) and the disable signal DIS_O is at the level 0 (inactive state). Therefore, the multiplexer 81 selects the input node “1”. Consequently, the command address signal CA_E<13:0> on the command address path P3 has the same waveform as the command address signal CA_O<13:0> on the command address path P4. Accordingly, the influences of NBTI and PBTI become the same between the command address path P3 and the command address path P4, so that there arises no difference in characteristics between the command address path P3 and the command address path P4. In the present example, the command address signal CA_E<13:0> on the command address path P3 is originally unnecessary and causes a malfunction in the subsequent circuit if this signal is supplied as it is. For this reason, the command address signal CA_E<13:0> is disabled in the subsequent circuit.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a clock divider configured to divide an original clock signal to generate a first clock signal and a second clock signal having a different phase from the first clock signal;
a first clock path;
a second clock path; and
a control circuit configured to:
in a first operation mode, supply at least one pulse of the first clock signal to the first clock path and at least one pulse of the second clock signal to the second clock path; and
in a second operation mode, supply one of the at least one pulse of the first clock signal and the at least one pulse of the second clock signal to the first clock path and supply one of the at least one pulse of the first clock signal and the at least one pulse of the second clock signal to the second clock path.

2. The apparatus of claim 1, wherein the control circuit includes:
a command input buffer configured to receive command signals externally provided;
a first latch circuit coupled to the command input buffer and the first clock path; and
a second latch circuit coupled to the command input buffer and the second clock path.

3. The apparatus of claim 2, wherein, in the second operation mode, one of the first latch circuit and the second latch circuit is configured to be deactivated.

4. The apparatus of claim 3, wherein, in the first operation mode, the first latch circuit is configured to store one or ones of the command signals in synchronism with the at least one pulse of the first clock signal and the second latch circuit is configured to store one or ones of the command signals in synchronism with the at least one pulse of the second clock signal.

5. The apparatus of claim 1, wherein, in the second operation mode, the control circuit is configured to supply one of the at least one pulse of the first clock signal and the at least one pulse of the second clock signal to both the first and second clock paths.

6. The apparatus of claim 5, wherein, in the second operation mode, the control circuit is configured to supply the at least one pulse of the first clock signal to both the first and second clock paths when a first command is issued synchronously with the first clock signal.

7. The apparatus of claim 6, wherein, in the second operation mode, the control circuit is configured to supply the at least one pulse of the second clock signal to both the first and second clock paths when the first command is issued synchronously with the second clock signal.

8. The apparatus of claim 7,
wherein the control circuit includes:
a first multiplexer having a first input node supplied with the at least one pulse of the first clock signal, a second input node supplied with the at least one pulse of the second clock signal, and a first output node coupled to the first clock path; and
a second multiplexer having a third input node supplied with the at least one pulse of the first clock signal, a fourth input node supplied with the at least one pulse of the second clock signal, and a second output node coupled to the second clock path,
wherein the first multiplexer is controlled by a first disable signal, and
wherein the second multiplexer is controlled by a second disable signal.

9. The apparatus of claim 8,
wherein the first and second disable signals are deactivated in the first operation mode, and
wherein one of the first and second disable signals is activated in the second operation mode.

10. The apparatus of claim 1, wherein the control circuit is configured to supply the at least one pulse of the first clock signal to the first clock path and supply the at least one pulse of the second clock signal to the second clock path when a first command is issued in the second operation mode.

11. The apparatus of claim 10, wherein the control circuit includes:
a first command control circuit configured to generate a first internal signal responsive to the first command and the first clock signal;
a second command control circuit configured to generate a second internal signal responsive to the first command and the second clock signal;
a first delay circuit configured to delay the first internal signal to generate a delayed first internal signal;
a second delay circuit configured to delay the second internal signal to generate a delayed second internal signal;
a first extraction circuit configured to extract the at least one pulse of the first clock signal based on one of the first internal signal and the delayed second internal signal; and
a second extraction circuit configured to extract the at least one pulse of the second clock signal based on one of the second internal signal and the delayed first internal signal.

12. The apparatus of claim 11,
wherein the first extraction circuit is configured to extract the at least one pulse of the first clock signal based on the first internal signal in the first operation mode, and
wherein the second extraction circuit is configured to extract the at least one pulse of the second clock signal based on the second internal signal in the first operation mode.

13. The apparatus of claim 12,
wherein the first extraction circuit is configured to extract the at least one pulse of the first clock signal based on the second delayed internal signal when the first command is issued synchronously with the second clock signal in the second operation mode, and
wherein the second extraction circuit is configured to extract the at least one pulse of the second clock signal based on the first delayed internal signal when the first command is issued synchronously with the first clock signal in the second operation mode.

14. An apparatus comprising:
a clock divider configured to divide an original clock signal to generate a first clock signal and a second clock signal having a different phase from the first clock signal;
a first extraction circuit configured to extract at least one pulse of the first clock signal when a first command is issued synchronously with the first clock signal;
a second extraction circuit configured to extract at least one pulse of the second clock signal when the first command is issued synchronously with the second clock signal;
a first multiplexer having a first input node supplied with the at least one pulse of the first clock signal, a second input node supplied with the at least one pulse of the second clock signal, and a first output node coupled to a first clock path; and
a second multiplexer having a third input node supplied with the at least one pulse of the first clock signal, a fourth input node supplied with the at least one pulse of the second clock signal, and a second output node coupled to a second clock path.

15. The apparatus of claim 14,
wherein the first multiplexer is configured to select the first input node in a first operation mode such that the at least one pulse of the first clock signal is supplied to the first clock path, and
wherein the second multiplexer is configured to select the fourth input node in the first operation mode such that the at least one pulse of the second clock signal is supplied to the second clock path.

16. The apparatus of claim 15, wherein the first multiplexer is configured to select the second input node when the first command is issued synchronously with the second clock signal in a second operation mode.

17. The apparatus of claim 16, wherein the second multiplexer is configured to select the third input node when the first command is issued synchronously with the first clock signal in the second operation mode.

18. An apparatus comprising:
a clock divider configured to divide an original clock signal to generate a first clock signal and a second clock signal having a different phase from the first clock signal;
a first control circuit configured to:
pass at least one pulse of the first clock signal when a first command is issued synchronously with the first clock signal;
pass at least one pulse of the second clock signal when the first command is issued synchronously with the second clock signal;
a first latch circuit configured to latch a second command synchronously with the at least one pulse of the first clock signal;
a second latch circuit configured to latch the second command synchronously with the at least one pulse of the second clock signal; and
a second control circuit configured to:
supply a second command output from the first latch circuit to a first command path when the first command is issued synchronously with the first clock signal in a first operation mode;
supply a second command output from the second latch circuit to a second command path when the first command is issued synchronously with the second clock signal in the first operation mode; and
supply the second command output from the first latch circuit to both the first and second command paths when the first command is issued synchronously with the first clock signal in a second operation mode.

19. The apparatus of claim 17, wherein the second control circuit is configured to supply the second command output from the second latch circuit to both the first and second command paths when the first command is issued synchronously with the second clock signal in the second operation mode.

20. The apparatus of claim 19,
wherein the second control circuit includes:
a first multiplexer having a first input node supplied with the second command output from the first latch circuit, a second input node supplied with the second command output from the second latch circuit, and a first output node coupled to the first command path; and
a second multiplexer having a third input node supplied with the second command output from the first latch circuit, a fourth input node supplied with the second command output from the second latch circuit, and a second output node coupled to the second command path,
wherein the first multiplexer is controlled by a first disable signal, and
wherein the second multiplexer is controlled by a second disable signal.
